(19) United States
(12) Patent Application Publication
(10) Pub. No.: US 2020/0111741 A1
(43) Pub. Date: Apr. 9, 2020

(54) VERTICAL ELECTRICAL FUSE

(71) Applicant: International Business Machines Corporation, Armonk, NY (US)

(72) Inventors: Chih-Chao Yang, Glenmont, NY (US); Baozhen Li, South Burlington, VT (US); Andrew Tae Kim, Poughkeepsie, NY (US)

(21) Appl. No.: 16/155,477

(22) Filed: Oct. 9, 2018

(51) Int. Cl. H01L 23/525

(52) U.S. Cl. CPC H01L 23/5256

(57) ABSTRACT

A vertical electrical fuse (eFuse) is provided that can be blown utilizing a relatively small current. The vertical eFuse is embedded in various dielectric material layers and includes a fuse link that is located between, and vertically connected to, first and second electrically conductive structures, the fuse link having a gouging feature at the bottom thereof.

### BACKGROUND

The present application relates to an electrical fuse (eFuse) and a method of forming the same. More particularly, the present application relates to a vertical eFuse that includes a fuse link that is located between, and vertically connected to, first and second electrically conductive structures, the fuse link having a gouging feature at the bottom thereof which permits the eFuse to be blown utilizing a relatively small current.

In addition to transistors, resistors, capacitors, and diodes, semiconductor devices also often contain fuses. These fuses may be used for several purposes. For example, fuses may be used within semiconductor devices for purposes of introducing or deleting customized circuit elements into a semiconductor device. In addition, fuses within semiconductor devices may be used for purposes of severing a non-operative portion of the semiconductor device and replacing that non-operative portion with a redundant semiconductor device fabricated on the same semiconductor substrate. Fuse elements may also be used to provide direct alternative current (DAC) trimming.

Selected fuses are usually blown by either a laser beam, or an electrical current, depending on the design of the fuse/device. In an electrical fuse design, electronically programmable fuses are blown by passing a current through the fuse link. The electrical current then causes a permanent change to the resistance of the fuse. The fuses that are blown are selected by one or more programming methods, which are generally known to those skilled in the art. Electronically programmable fuses, also called eFuses, have become popular because of the circuit and systems design flexibility that they provide. The eFuse can be programmed even when the chip is mounted in the package and installed in the system. For example, users can tailor a design to the specific needs of an application after the product is installed. The eFuse also enables the freedom to alter the design, or fix problems that may occur during the life of the product.

In conventional eFuses, the fuse link dimension is limited by the allowable photolithographic minimal dimensions. Programming of such conventional eFuses typically requires a substantial amount of current, which is undesirable in current technology node devices using low driving current. In view of the above, there is a need for providing a semiconductor structure containing at least one eFuse that can be blown utilizing a smaller current than conventional eFuses.

### SUMMARY

A vertical electrical fuse (eFuse) is provided that can be blown utilizing a relatively small current. The vertical eFuse is embedded in various dielectric material layers and includes a fuse link that is located between, and vertically connected to, first and second electrically conductive structures, the fuse link having a gouging feature at the bottom thereof.

In one aspect of the present application, a semiconductor structure is provided. In one embodiment, the semiconductor structure includes at least one vertical eFuse embedded in a dielectric material stack and comprising a fuse link that is located between, and vertically connected to, a first electrically conductive structure and a second electrically conductive structure, the fuse link having a bottom portion that includes a gouging feature.

In another aspect of the present application, a method of forming a semiconductor structure is provided. In one embodiment, the method includes forming at least one opening partially into a second dielectric material layer, wherein the at least one opening is located over a first electrically conductive structure that is embedded in a first dielectric material layer. A directional ion-sputtering process is performed to remove physically exposed portions of the second dielectric material layer at a bottom of the at least one opening and to provide a fuse link region that includes a gouging feature that physically exposes a portion of the first electrically conductive structure. A fuse element is formed into the fuse link region to provide a fuse link having the gouging feature at the bottom thereof. A second electrically conductive structure is formed in a third dielectric material layer and above the second dielectric material layer, wherein the second electrically conductive structure directly contacts a surface of the fuse link.

### BRIEF DESCRIPTION OF THE DRAWINGS

FIG. 1 is a cross sectional view of an exemplary semiconductor structure that can be employed in fabricating a vertical eFuse in accordance with an embodiment of the present application, the exemplary semiconductor structure including a plurality of first electrically conductive structures embedded in a first dielectric material layer.

FIG. 2A is a cross sectional view of the exemplary semiconductor structure of FIG. 1 after forming a second dielectric material layer, and forming a plurality of openings partially into the second dielectric material layer.

FIG. 2B is a cross sectional view of the exemplary semiconductor structure of FIG. 1 after forming a dielectric capping layer and a second dielectric material layer, and forming a plurality of openings partially into the second dielectric material layer.

FIG. 3 is a cross sectional view of the exemplary semiconductor structure of FIG. 2A after performing a directional ion-sputtering process to remove physically exposed portions of the second dielectric material layer at the bottom of each opening and to provide a fuse link region that includes a gouging feature at the bottom thereof that physically exposes a portion of one of the first electrically conductive structures.

FIG. 4 is a cross sectional view of the exemplary semiconductor structure of FIG. 3 after forming a fuse element into each fuse link region to provide a fuse link having the gouging feature at the bottom thereof.

FIG. 5A is a cross sectional view of the exemplary semiconductor structure of FIG. 4 after forming a third dielectric material layer above the second dielectric material layer, and forming a plurality of second electrically conductive structures in the third dielectric material layer, wherein each second electrically conductive structure directly contacts a surface of one of the underlying fuse links.

FIG. 5B is a cross sectional view of the exemplary semiconductor structure of FIG. 4 after forming a third dielectric material layer above the second dielectric material layer, and forming a second electrically conductive structure in the third dielectric material layer, wherein the second electrically conductive structure directly contacts a surface of each of the underlying fuse links.

FIGS. 5C-5D are cross sectional views of the exemplary semiconductor structure of FIG. 4 after forming a dielectric capping layer and a third dielectric material layer above the second dielectric material layer, and forming a plurality of second electrically conductive structures in the third dielectric material layer and the underlying dielectric capping layer, wherein each second electrically conductive structure directly contacts a surface of one of the underlying fuse links.

FIG. 6 is a cross sectional after programming of the vertical eFuse shown in FIG. 5C.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

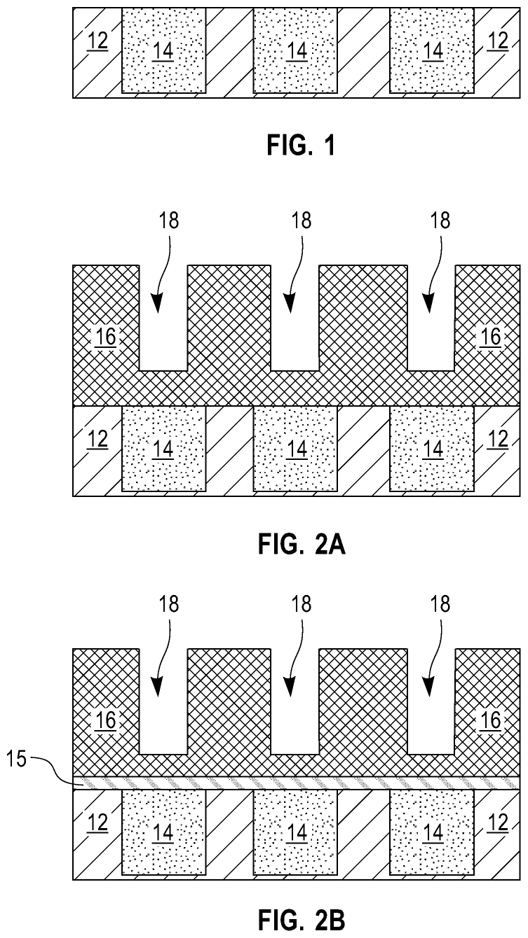

Referring first to FIG. 1, there is illustrated an exemplary semiconductor structure that can be employed in fabricating a vertical eFuse in accordance with an embodiment of the present application, the exemplary semiconductor structure including a plurality of first electrically conductive structures 14 embedded in a first dielectric material layer 12. Although the present application describes and illustrates a plurality of first electrically conductive structures 14 embedded in the first dielectric material layer 12, the present application contemplates an embodiment in which only a single first electrically conductive structure 14 is embedded in the first dielectric material layer 12.

Although not shown, the exemplary semiconductor structure of FIG. 1 can be formed on a surface of a substrate. In some embodiments, the substrate may include a front-end-of-the-line (FEOL) level. The FEOL level includes a semiconductor substrate having one or more semiconductor devices such, as, for example, transistors, capacitors, resistors, and etc. located thereon. In other embodiments, the substrate may include one or more interconnect levels of a multilayered interconnect structure. In such an embodiment, each interconnect level would include one or more electrically conductive structures embedded in an interconnect dielectric material. A FEOL level is typically present beneath the lowest level of the multilayered interconnect structure.

The first dielectric material layer 12 may be composed of an inorganic dielectric material or an organic dielectric material. In some embodiments, the first dielectric material layer 12 may be porous. In other embodiments, the first dielectric material layer 12 may be non-porous. Examples of suitable dielectric materials that may be employed as the first dielectric material layer 12 include, but are limited to, silicon dioxide, undoped or doped silicate glass, silsesquioxanes, C doped oxides (i.e., organosilicates) that include atoms of Si, C, O and H, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

In some embodiments, the first dielectric material layer 12 may have a dielectric constant (all dielectric constants mentioned herein are measured relative to a vacuum, unless otherwise stated) that is about 4.0 or less. In one example, the first dielectric material layer 12 can have a dielectric constant of 2.8 or less. These dielectrics generally having a lower parasitic cross talk as compared to dielectric materials whose dielectric constant is greater than 4.0.

The first dielectric material layer 12 can be formed by a deposition process such as, for example, chemical vapor deposition (CVD), plasma enhanced chemical vapor deposition (PECVD) or spin-on coating. The first dielectric material layer 12 can have a thickness from 50 nm to 250 nm. Other thicknesses that are lesser than 50 nm, and greater than 250 nm can also be employed in the present application.

At least one opening (not show) is then formed into the first dielectric material layer 12. Each opening that is formed will subsequently house a first electrically conductive structure 14. In the present application, each opening that is formed in the first dielectric material layer 12 may be a via opening, a line opening or a combined via/line opening. Each opening may be formed by lithography and etching. Lithography includes applying a photoresist material over a material or material stack to be patterned, exposing the photoresist material to a pattern of irradiation, and developing the exposed photoresist material. The etching may include an anisotropic etch etching process such as, for example, reactive ion etching. In embodiments in which a combined via/line opening is formed, a second iteration of lithography and etching may be used to form such an opening.

In some embodiments, each opening extends through the entire depth of the first dielectric material layer 12. In other embodiments, each opening may extend partially through the first dielectric material layer 12. In yet further embodiments, and when multiple openings are formed, each opening may have a same depth, or the openings may have different depth.

An electrically conductive metal or metal alloy is formed into each of the openings. The electrically conductive metal or metal alloy provides the first electrically conductive structures 14 of the present application. The electrically conductive metal or metal alloy that provides the first electrically conductive structures 14 may be composed of copper (Cu), aluminum (Al), tungsten (W), cobalt (Co), ruthenium (Ru), nickel (Ni), platinum (Pt), rhodium (Rh) or an alloy thereof such as, for example, a Cu—Al alloy. The electrically conductive metal or metal alloy can be formed utilizing a deposition process such as, for example, CVD, PECVD, sputtering, chemical solution deposition or plating. In one embodiment, a bottom-up plating process is employed in forming the electrically conductive metal or metal alloy. In some embodiments, the electrically conductive metal or metal alloy is formed above the topmost surface of the first dielectric material layer 12.

Following the deposition of the electrically conductive metal or metal alloy, a planarization process such as, for example, chemical mechanical polishing (CMP) and/or grinding, can be used to remove all portions of the electrically conductive metal or metal alloy (i.e., overburden material) that are present outside each of the openings forming the first electrically conductive structure 14. The planarization stops on a topmost surface of the first dielectric material layer 12. If present, the planarization process also removes the diffusion barrier material from the topmost surface of the first dielectric material layer 12. The remaining electrically conductive metal or metal alloy that is present in each opening constituents one of the first electrically conductive structures 14 of the present application. As is shown, each first electrically conductive structure 14 has a topmost surface that is coplanar with a topmost surface of the first dielectric material layer 12.

In some embodiments (not shown), a diffusion barrier liner can be formed into the opening such that it is present between the first dielectric material layer 12 and the first electrically conductive structure. A diffusion barrier material is first formed into the opening 14 and on an exposed topmost surface of the first dielectric material layer 12. The diffusion barrier liner may include Ta, TaN, Ti, TiN, Ru, RuN, RuTa, RuTaN, W, WN or any other material that can serve as a barrier to prevent a conductive material from diffusing there through. The thickness of the diffusion barrier liner may vary depending on the deposition process used as well as the material employed. In some embodiments, the diffusion barrier liner may have a thickness from 2 nm to 50 nm; although other thicknesses for the diffusion barrier liner are contemplated and can be employed in the present application as long as the diffusion barrier liner does not entirely fill the opening. The diffusion barrier material that provides the diffusion barrier liner can be formed by a deposition process including, for example, chemical vapor deposition (CVD), plasma enhanced chemical vapor deposition (PECVD), atomic layer deposition (ALD), physical vapor deposition (PVD), sputtering, chemical solution deposition or plating. When present, the diffusion barrier material is deposited into the opening prior to the electrically conductive metal or metal alloy.

Referring now to FIG. 2A, there is illustrated the exemplary semiconductor structure of FIG. 1 after forming a second dielectric material layer 16, and forming a plurality of openings 18 partially into the second dielectric material layer 12. Each opening 18 is located over one of the first electrically conductive structures 14. Although a plurality of openings 18 are described and illustrated, the present application contemplates embodiments in which a single opening 18 is formed.

The second dielectric material layer 16, which is formed on an entirety of the topmost surface of the exemplary structure shown in FIG. 1, may include one of the dielectric materials mentioned above for the first dielectric material layer 12. In one embodiment, the second dielectric material layer 16 is composed of a same dielectric material as the first dielectric material layer 12. In another embodiment, the second dielectric material layer 16 is composed of a dielectric material that is compositionally different from the dielectric material that provides the first dielectric material layer 12. The second dielectric material layer 16 may be formed utilizing one of the deposition processes mentioned above in forming the first dielectric material layer 12. The second dielectric material layer 16 may have a thickness that is in the thickness range provided above for the first dielectric material layer 12.

The openings 18 that are formed partially into the second dielectric material layer 16 can be formed by lithography and etching as defined above. The openings 18 are via openings that have a width that is less than a width of the underlying first electrically conductive structures 14. In one embodiment, each opening 18 has a width from 10 nm to 200 nm, while each first electrically conductive structure 14 has a width from 10 nm to 400 nm.

Referring now to FIG. 2B, there is illustrated the exemplary semiconductor structure of FIG. 1 after forming a dielectric capping layer 15 and a second dielectric material layer 16, and forming a plurality of openings 18 partially into the second dielectric material layer 16. The structure shown in FIG. 2B is identical to the structure shown in FIG. 2A except for the presence of the dielectric capping layer 15.

The dielectric capping layer 15, which is formed on an entirety of the topmost surface of the exemplary structure shown in FIG. 1, may include any dielectric capping material including, for example, silicon carbide (SiC), silicon nitride (Si₃N₄), silicon dioxide (SiO₂), a carbon doped oxide, a nitrogen and hydrogen doped silicon carbide (SiC(N,H)) or a multilayered stack of at least one of the aforementioned dielectric capping materials. The dielectric capping material that provides the dielectric capping layer 15 may be formed utilizing a deposition process such as, for example, CVD, PECVD, ALD, chemical solution deposition or evaporation. Dielectric capping layer 15 may have a thickness from 10 nm to 100 nm. Other thicknesses that are lesser than 10 nm, or greater than 100 nm may also be used as the thickness of the dielectric capping layer 15.

The second dielectric material layer 16, as defined above, is then formed on an entirety of the dielectric capping layer 15, and openings 18 are formed partially into the second dielectric material layer 16 by lithography and etching, as also defined above. As is the previous embodiment illustrated in FIG. 2A, the widths of each opening 18 shown in FIG. 2B is less than the widths of each first electrically conductive structure 14.

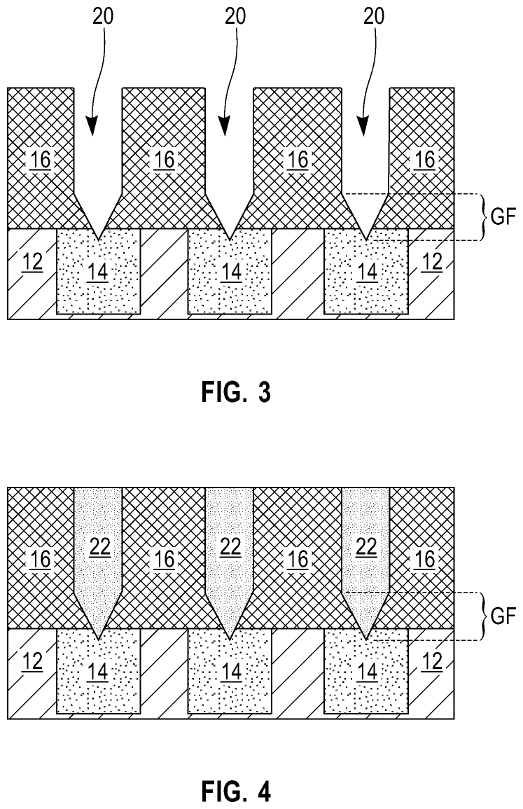

Referring now to FIG. 3, there is illustrated the exemplary semiconductor structure of FIG. 2A after performing a directional ion-sputtering process to remove physically exposed portions of the second dielectric material layer 16 at the bottom of each opening 18 and to provide a fuse link region 20 that includes a gouging feature, GF, at the bottom thereof. The gouging feature, GF, physically exposes a portion of one of the first electrically conductive structures 14 and may present below a topmost surface of the remaining first electrically conductive structure 14. The directional ion-sputtering process may remove an upper portion of the underlying first electrically conductive structure 14.

The directional ion-sputtering process is conducted with a gas source including, but not limited to, argon (Ar), helium (He), xenon (Xe), neon (Ne), krypton (Kr), radon (Rn), nitrogen (N₂) or hydrogen (H₂). Notably, ions of one of the aforementioned gas sources is generated, and the ions bombard and remove the physically exposed portion of the second dielectric material 16 within each opening 18 providing the fuse link region 20 that includes a gouging feature, GF, at the bottom thereof. The directional ion-sputtering process may be performed at a temperature from 10° C. to 350° C.

The gouging feature, GF, is in the shape of an inverted triangle in which the base portion of the triangle is located above a tip portion of the triangle. The tip portion of the triangle may extend into the first electrically conductive structure 14. The tip portion of the triangle is connected to the base portion of the triangle be faceted, i.e., slanted, sidewalls which extend inward from the base portion to the tip portion. The tip portion may extend below a topmost surface of the first electrically conductive structure 14.

Referring now to FIG. 4, there is illustrated the exemplary semiconductor structure of FIG. 3 after forming a fuse element into each fuse link region 20 including the gouging feature, GF, to provide a fuse link 22 that has a bottom portion that has a gouging feature, GF, as defined above.

The fuse element may include aluminum (Al) copper (Cu), silicon (Si), nickel (Ni) or alloys thereof. The fuse element may be formed utilizing a deposition process such as, for example, CVD, PECVD, ALD, or sputtering. A planarization process such as, for example, chemical mechanical polishing (CMP) may follow the deposition of the fuse element.

As is shown in FIG. 4, each fuse link 22 has an upper surface that is coplanar with a topmost surface of the second dielectric material layer 16 and the tip portion of the gouging feature, GF, of the fuse link 22 is in direct physically contact with a surface of one of the first electrically conductive structures 14. The tip portion of each fuse link 22 may extend below a topmost surface of the first electrically conductive structure 14.

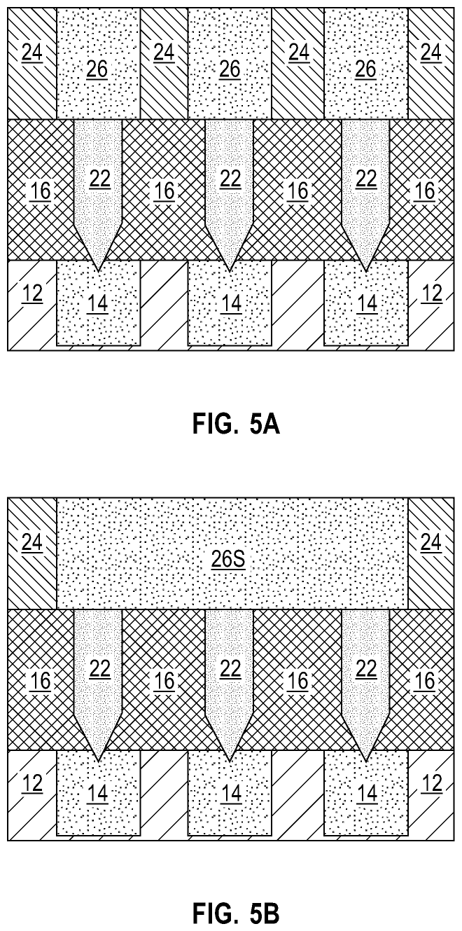

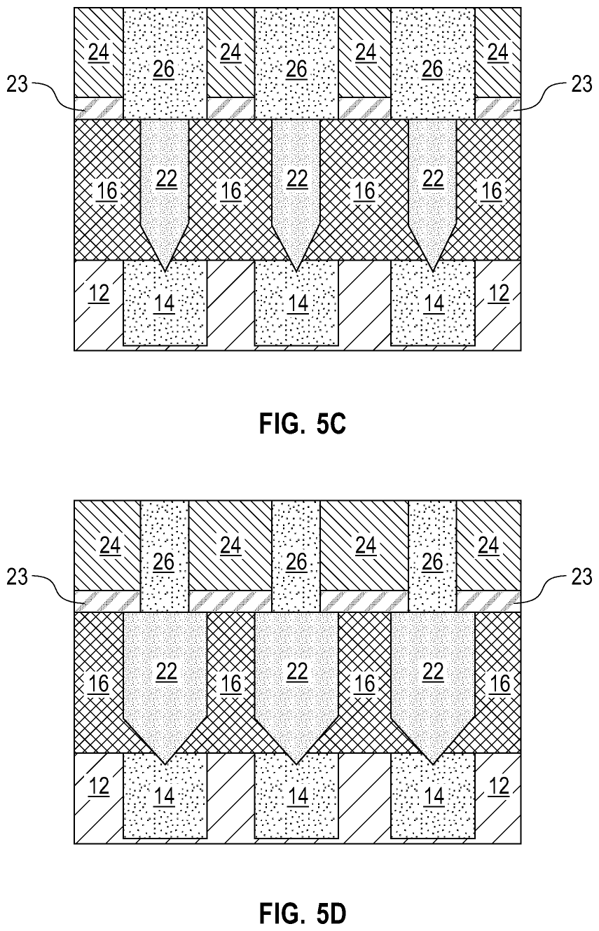

Referring now to FIG. 5A, there is illustrated the exemplary semiconductor structure of FIG. 4 after forming a third dielectric material layer 24 above the second dielectric material layer 16, and forming a plurality of second electrically conductive structures 26 in the third dielectric material layer 14, wherein each second electrically conductive structure 26 directly contacts a surface of one of the underlying fuse links 22. Collectively, and in this embodiment, the first dielectric material layer 12, the second dielectric material layer 16, and the third dielectric material layer 24 form a dielectric material stack.

The third dielectric material layer 24 may include one of the dielectric materials mentioned above for the first dielectric material layer 12. In one embodiment, the third dielectric material layer 24 is composed of a same dielectric material as the first dielectric material layer 12 and/or the second dielectric material layer 16. In another embodiment, the third dielectric material layer 24 is composed of a dielectric material that is compositionally different from the dielectric material that provides the first dielectric material layer 12 and/or the second dielectric material layer 16. The third dielectric material layer 24 may be formed utilizing one of the deposition processes mentioned above in forming the first dielectric material layer 12. The third dielectric material layer 24 may have a thickness that is in the thickness range provided above for the first dielectric material layer 12.

The second electrically conductive structures 26 are formed utilizing the technique mentioned above in forming the first electrically conductive structures 14. Each second electrically conductive structure 26 may include one of the electrically conductive metals or metal alloys mentioned above for the first electrically conductive structures 14. In one embodiment, each second electrically conductive structure 26 includes a same electrically conductive metal or metal alloy as the first electrically conductive structures 14. In another embodiment, each second electrically conductive structure 26 includes an electrically conductive metal or metal alloy that is compositionally different from the electrically conductive metal or metal alloy that provides the first electrically conductive structures 14. Each second electrically conductive structure 26 has a topmost surface that is coplanar with a topmost surface of the third dielectric material.

The exemplary structure of FIG. 5A includes at least one vertical eFuse (14/22/26) embedded in a dielectric material stack (12, 16 and 24). Each vertical eFuse includes a fuse link 22 that is located between, and vertically connected to, a first electrically conductive structure 14 and a second electrically conductive structure 26, the fuse link 22 having a bottom portion that includes a gouging feature. The first and second electrically conductive structures (14 and 26) serve as the anode/cathode structure of the vertical eFuse. In this embodiment, each first and second electrically conductive structure (14 and 26) has a width that is greater than a width of the fuse link 22. In this exemplary structure, the vertical eFuse (14/22/26) are spaced apart by a portion of the dielectric material stack (12, 16 and 24).

Referring now to FIG. 5B, there is illustrated the exemplary semiconductor structure of FIG. 4 after forming a third dielectric material layer 24 above the second dielectric material layer 16, and forming a single, second electrically conductive structure 26S in the third dielectric material layer 24, wherein the second electrically conductive structure 26S is a shared structure that directly contacts a surface of each of the underlying fuse links 22. In this embodiment, each vertical eFuse is interconnected interconnect by the second electrically conductive structure 26S such that each fuse link 22 directly contacts the second electrically conductive structure 26S.

The exemplary structure of FIG. 5B can be formed utilizing the same basic processing steps as described above for forming the exemplary structure shown in FIG. 5A except that a single, common second electrically conductive structure 26S is formed rather than individual second electrically conductive structures 26 as shown in FIG. 5A. In some embodiments (not shown), a dielectric capping layer can be formed between the second and third dielectric material layers.

Collectively, and in this embodiment, the first dielectric material layer 12, the second dielectric material layer 16, and the third dielectric material layer 24 form a dielectric material stack. The exemplary structure of FIG. 5B includes at least one vertical eFuse (14/22/26S) embedded in a dielectric material stack (12, 16 and 24). Each vertical eFuse includes a fuse link 22 that is located between, and vertically connected to, a first electrically conductive structure 14 and a second electrically conductive structure 26S, the fuse link 22 having a bottom portion that includes a gouging feature; in this embodiment the second electrically conductive structure 26S is shared among the various eFuses providing a common element.

Referring now to FIGS. 5C-5D, there are illustrated the exemplary semiconductor structure of FIG. 4 after forming a dielectric capping layer 23 and a third dielectric material layer 24 above the second dielectric material layer 16, and forming a plurality of second electrically conductive structures 26 in the third dielectric material layer 24 and the underlying dielectric capping layer 23, wherein each second electrically conductive structure 26 directly contacts a surface of one of the underlying fuse links 22. Collectively, and in these embodiments, the first dielectric material layer 12, the second dielectric material layer 16, the dielectric capping layer 23, and the third dielectric material layer 24 form a dielectric material stack.

The exemplary structures of FIGS. 5C and 5D can be formed utilizing the same basic processing steps as described above for forming the exemplary structure shown in FIG. 5A except that dielectric capping layer 23 is formed between the second and third dielectric material layers. The dielectric capping layer 23 may include one of the dielectric materials mentioned above for dielectric capping layer 15. The dielectric capping layer 23 may be formed utilizing one of the deposition techniques mentioned above for forming dielectric capping layer 15. The dielectric capping layer 23 may have a thickness with the thickness range mentioned above for dielectric capping layer 15.

The exemplary structures of FIGS. 5C and 5D differ in that each second electrically conductive structure 26 shown FIG. 5C has a width that is greater than a width of the fuse links 22, while in FIG. 5D, each second electrically conductive structure 26 has a width that is lesser than a width of an upper portion of the fuse links 22. The exemplary structures of FIGS. 5C and 5D includes at least one vertical eFuse (14/22/26) embedded in a dielectric material stack (12, 16, 23 and 24). Each vertical eFuse includes a fuse link 22 that is located between, and vertically connected to, a first electrically conductive structure 14 and a second electrically conductive structure 26, the fuse link 22 having a bottom portion that includes a gouging feature. The first and second electrically conductive structures (14 and 26) serve as the anode/cathode structure of the vertical eFuse. In this embodiment, each first and second electrically conductive structure (14 and 26) has a width that is greater than a width of the fuse link 22. In this exemplary structure, the vertical eFuse (14/22/26) are spaced apart by a portion of the dielectric material stack (12, 16, 23 and 24).

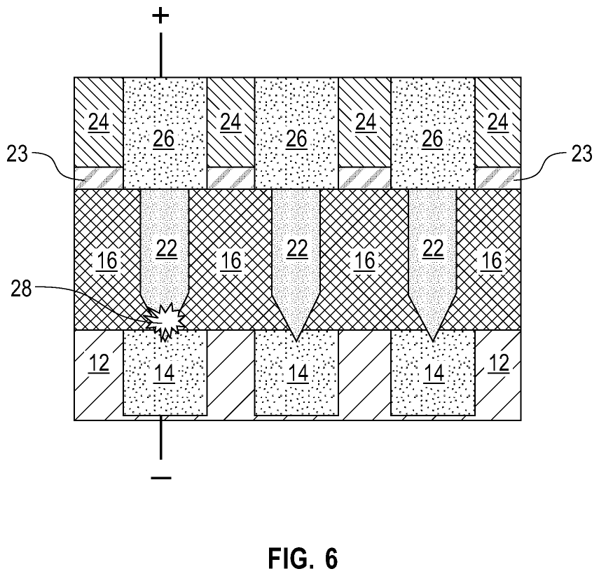

The exemplary structures shown in FIG. 5A-5D are prior to programming. FIG. 6 illustrates a blown vertical eFuse of the exemplary structure shown in FIG. 5C after programming. As is shown, the blowing of the vertical eFuse shown in FIG. 6 results in removing a portion of the gouging feature from the fuse link 22 such that the remaining fuse link 22 does not contact the first electrically conductive structure 14. In FIG. 6, element 28 denotes a gap that is formed by such a process. The blowing of the vertical eFuse requires a relative low current due to the presence of the gouging feature, and can be performed utilizing means well known to those skilled in the art.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor structure comprising:
at least one vertical eFuse embedded in a dielectric material stack and comprising a fuse link that is located between, and vertically connected to, a first electrically conductive structure and a second electrically conductive structure, the fuse link having a bottom portion that includes a gouging feature.

2. The semiconductor structure of claim 1, wherein the dielectric material stack comprises a first dielectric material layer, a second dielectric material layer and a third dielectric material layer, wherein the first electrically conductive structure is embedded in the first dielectric material layer, the fuse link is embedded in the second dielectric material layer, and wherein the second electrically conductive structure is embedded in the third dielectric material layer.

3. The semiconductor structure of claim 2, wherein a dielectric capping layer separates the first dielectric material layer from the second dielectric material layer.

4. The semiconductor structure of claim 2, wherein a dielectric capping layer separates the second dielectric material layer from the third dielectric material layer.

5. The semiconductor structure of claim 1, wherein the gouging feature has a shape of an inverted triangle including a base portion and a tip portion, wherein the base portion and the tip portion are connected by faceted sidewalls, and wherein the tip portion extends below a topmost surface of the first electrically conductive structure.

6. The semiconductor structure of claim 1, wherein the second electrically conductive structure has a width that is less than a width of the fuse link.

7. The semiconductor structure of claim 1, wherein the second electrically conductive structure has a width that is greater than a width of the fuse link.

8. The semiconductor structure of claim 1, wherein the at least one vertical eFuse comprises a plurality of vertical eFuses, wherein each vertical eFuse of the plurality of vertical eFuses comprises a fuse link having the gouging feature.

9. The semiconductor structure of claim 8, wherein each vertical eFuse of the plurality of vertical eFuses is interconnected by the second electrically conductive structure such that each fuse link directly contacts the second electrically conductive structure.

10. The semiconductor structure of claim 8, wherein each vertical eFuse is spaced apart from each other by a portion of the dielectric material stack.

11. A method of forming a semiconductor structure, the method comprising:
forming at least one opening partially into a second dielectric material layer, wherein the at least one opening is located over a first electrically conductive structure that is embedded in a first dielectric material layer;
performing a directional ion-sputtering process to remove physically exposed portions of the second dielectric material layer at a bottom of the at least one opening and to provide a fuse link region that includes a gouging feature that physically exposes a portion of the first electrically conductive structure;
forming a fuse element into the fuse link region to provide a fuse link having the gouging feature at the bottom thereof; and
forming a second electrically conductive structure in a third dielectric material layer and above the second dielectric material layer, wherein the second electrically conductive structure directly contacts a surface of the fuse link.

12. The method of claim 11, wherein the forming of the least one opening comprises forming a plurality of openings partially into the second dielectric material, wherein the directional ion-sputtering process removes physically exposed portions of the second dielectric material layer at the bottom of each of the openings and provides a plurality of fuse link regions, each fuse link region includes the gouging feature that physically exposes a portion of one of the first electrically conductive structures, and further wherein the fuse element is formed into each fuse link region to provide a plurality of fuse links having the gouging feature.

13. The method of claim 12, wherein the second electrically conductive structure contacts a surface of each fuse link.

14. The method of claim 12, wherein the forming of the second electrically conductive structure comprises forming a plurality of second electrically conductive structures, wherein each second electrically conductive structure contacts the surface of one of the fuse links.

15. The method of claim 14, wherein each second electrically conductive structure has a width that is greater than a width of an upper portion the fuse links.

16. The method of claim 14, wherein each second electrically conductive structure has a width that is less than a width of the fuse links.

17. The method of claim 11, wherein the directional ion-sputtering process further removes a portion of the first electrically conductive structure such that a tip portion of the gouging feature extends below a topmost surface of the first electrically conductive structure.

18. The method of claim 11, further comprising forming a dielectric capping layer between the first and second dielectric material layers.

19. The method of claim 11, further comprising forming a dielectric capping layer between the second and third dielectric material layers.

20. The method of claim 11, wherein the gouging feature has a shape of an inverted triangle including a base portion and a tip portion, wherein the base portion and the tip portion are connected by faceted sidewalls.
